(19) United States
(12) Patent Application Publication
(10) Pub. No.: US 2015/0015342 A1
(43) Pub. Date: Jan. 15, 2015

(54) ON-CHIP OSCILLATING METHOD ABLE TO CALIBRATE FREQUENCY THEREOF AND ASSOCIATED APPARATUS

(71) Applicant: JMicron Technology Corp., Hsin-Chu (TW)

(72) Inventors: Yi-Ren Huang, Tainan City (TW); Tang-Hui Yang, New Taipei City (TW); Guo-Hau Lee, Taipei City (TW)

(21) Appl. No.: 14/325,330

(22) Filed: Jul. 7, 2014

(30) Foreign Application Priority Data
Jul. 10, 2013 (TW) 102124808

(51) Int. Cl. H03L 7/00

(52) U.S. Cl. CPC H03L 7/00
USPC 331/177 R

(57) ABSTRACT

An on-chip oscillating method which is able to calibrate a frequency of an on-chip oscillator includes: utilizing the on-chip oscillator to generate a predetermined frequency output; receiving an external data input from an off-chip data source; generating a comparison result by comparing the predetermined frequency output with the external data input; and calibrating the predetermined frequency output by utilizing the comparison result. An on-chip oscillating apparatus which is able to calibrate its frequency includes: the on-chip oscillator, arranged to generate a predetermined frequency output; a receiving unit, arranged for receiving an external data input from an off-chip data source; and a comparison unit, arranged for generating a comparison result for calibrating the predetermined frequency output by comparing a predetermined frequency output with an external data input from an off-chip data source.

### BACKGROUND OF THE INVENTION

1. Field of the Invention

The disclosed embodiments of the present invention relate to frequency calibration mechanism, and more particularly, to an on-chip oscillating method which is able to calibrate its frequency, and a related apparatus.

2. Description of the Prior Art

A conventional crystal oscillator is an electronic component which utilizes the piezoelectric effect of a quartz crystal to output a high precision oscillating frequency. The crystal oscillator is usually disposed outside a chip, and outputs a reference clock to the chip via a trace on a printed circuit board (PCB). With the development of integrated circuits, consumers' demand for mobile devices of a compact size and low price has resulted in on-chip oscillators being available on the market. An on-chip oscillator needs to be carefully adjusted in the factory so as to ensure it can operate with acceptable accuracy. Even with this adjustment, users may also need to further adjust the on-chip oscillator themselves, as on-chip oscillators are sensitive to changes in temperature. This is highly inconvenient.

Therefore, there is an urgent need for a novel method that can improve on a conventional on-chip oscillator.

### SUMMARY OF THE INVENTION

One of the objectives of the present invention is to provide an on-chip oscillating method which is able to calibrate the frequency of an on-chip oscillator, and a related apparatus, to solve the aforementioned issues.

According to a first embodiment of the present invention, an on-chip oscillating method which can calibrate frequency of an on-chip oscillator is disclosed. The on-chip oscillating method includes: utilizing an on-chip oscillator to generate a predetermined frequency output; receiving an external data input from an off-chip data source; generating a comparison result by comparing the predetermined frequency output with the external data input; and calibrating the predetermined frequency output by utilizing the comparison result.

According to a second embodiment of the present invention, an on-chip oscillating apparatus which is able to calibrate its frequency is disclosed. The on-chip oscillating apparatus includes an on-chip oscillator and a calibration unit. The on-chip oscillator is arranged to generate a predetermined frequency output. The calibration unit is arranged to generate a comparison result by comparing the predetermined frequency output with an external data input received from an off-chip data source, and to calibrate the predetermined frequency output according to the comparison result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional on-chip oscillator.

FIG. 2 is a diagram illustrating an on-chip oscillating apparatus according to an embodiment of the present invention.

FIG. 3 is a flowchart illustrating an on-chip oscillating method according to another embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

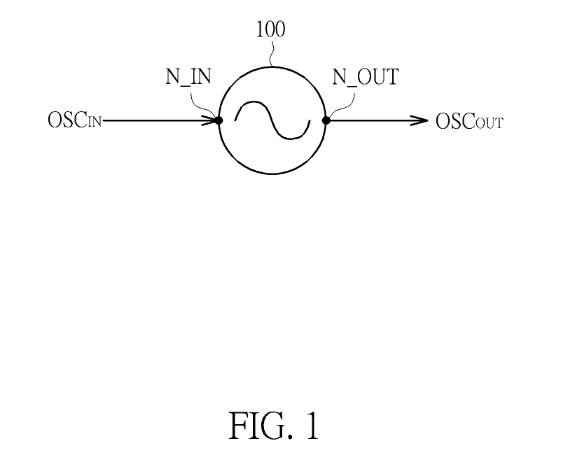

Please refer to FIG. 1, which is a diagram illustrating a conventional on-chip oscillator 100. The on-chip oscillator 100 includes an input terminal N_IN and an output terminal N_OUT. Although a designer can optimize the on-chip oscillator 100 in the factory, the on-chip oscillator 100 may still become inaccurate due to variations in temperature or supply voltage. To compensate for these variations, an on-chip oscillator input OSC_{IN} is input to the on-chip oscillator 100 via the input terminal N_IN, so that adjustment can be made to the on-chip oscillator 100 in a convenient manner. For instance, when the temperature or the supply voltage changes, users can adjust the on-chip oscillator 100 by adjusting the on-chip oscillator input OSC_{IN}. When the precision of the on-chip oscillator output OSC_{OUT} drifts over a tolerated level, users can perform fine or even coarse-tuning on the on-chip oscillator 100 through the on-chip oscillator input OSC_{IN}. In this way, the adjusted on-chip oscillator 100 meets precision requirements. The present invention further discloses an automatic frequency calibration method which automatically adjusts the on-chip oscillator input OSC_{IN} to realize frequency calibration without manual adjustment by a user. Details are provided in the following paragraphs.

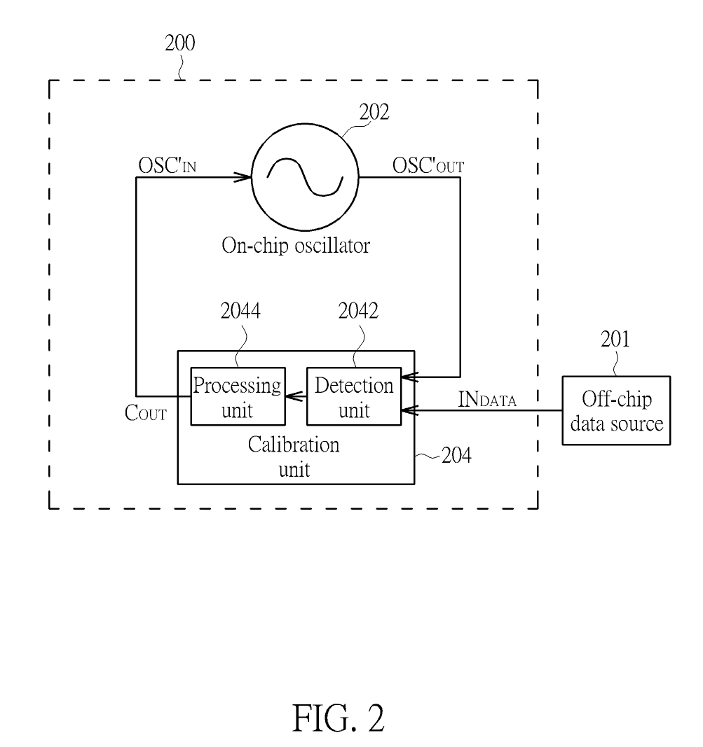

Please refer to FIG. 2, which is a diagram illustrating an on-chip oscillating apparatus 200 according to an embodiment of the present invention. The on-chip oscillating apparatus 200 includes an on-chip oscillator 202 and a calibration unit 204. The on-chip oscillator 202 may be an LC oscillator, a relaxation oscillator or a ring oscillator. Is should be noted that the on-chip oscillator 202 of the on-chip oscillating apparatus 200 is not limited to the aforementioned oscillator types. The calibration unit 204 includes a detection unit 2042 and a processing unit 2044.

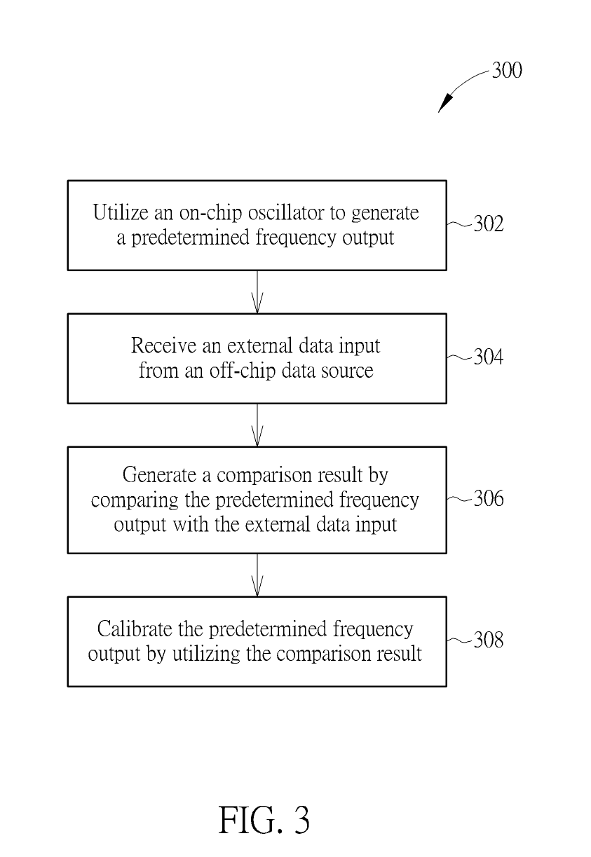

Please refer to FIG. 3, which is a flowchart illustrating an on-chip oscillating method 300 according to another embodiment of the present invention. Provided that substantially the same result is achieved, the steps of the flowchart shown in FIG. 3 need not be in the exact order shown and need not be contiguous; that is, other steps can be intermediate. Some steps in FIG. 3 may be omitted according to various types of embodiments or requirements. The method may be briefly summarized as follows:

Step 302: Utilize an on-chip oscillator to generate a predetermined frequency output;

Step 304: Receive an external data input from an off-chip data source;

Step 306: Generate a comparison result by comparing the predetermined frequency output with the external data input; and

Step 308: Calibrate the predetermined frequency output by utilizing the comparison result.

As shown in FIG. 2, the calibration unit 204 of the on-chip oscillating apparatus 200 simultaneously receives a predetermined frequency output OSC′_{OUT} from an output terminal of the on-chip oscillator 202 and an external data input IN_{DATA} (e.g. data types with certain fixed frequency as prescribed in USB 3.0, such as TSEQ, TS1, TS2) from an off-chip data source 201 (e.g. a USB 3.0 transmitter), and utilizes the detection unit 2042 of the calibration unit 204 to compare the predetermined frequency output OSC′_{OUT} with the external data input IN_{DATA}. The detection unit 2042 may perform phase difference detection upon the predetermined frequency output OSC′_{OUT} and the external data input IN_{DATA}. It should be noted that the detection unit 2042 of the oscillating apparatus 200 is not limited to perform phase difference detection. In alternative designs, the detection unit 2042 may perform frequency difference detection upon the predetermined frequency output OSC′_{OUT} and the external data input IN_{DATA}. In addition, the off-chip data source 201 of this embodiment may be a link partner corresponding to the local side to which the on-chip oscillating apparatus 200 belongs. The external data input IN_{DATA} may be a data signal transmitted from the link partner to the local side, and the main frequency of the data signal is a predetermined frequency of the on-chip oscillating apparatus 200. This is for illustrative purposes only. The external data input IN_{DATA} is not limited to the data signal transmitted from the link partner to the local side. In alternative designs, the external data input IN_{DATA} may be a reference clock transmitted from the link partner to the local side.

The detection unit 2042 provides the detected result to the processing unit 2044 to derive a comparison result C_{OUT}, which is directly fed back to an input terminal of the on-chip oscillator 202 to act as an oscillator input OSC′_{IN} which satisfies the requirement of the on-chip oscillator 202. Specifically, the detection unit 2042 adjusts the oscillating apparatus 200 on the fly without requiring manual adjustment by users according to the predetermined frequency output OSC′_{OUT} outputted by the output terminal of the oscillating apparatus 200. Hence, frequency offset induced by non-ideal effects such as variations in temperature or supply voltage can be calibrated immediately.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An on-chip oscillating method which is able to calibrate a frequency of an on-chip oscillator, the method comprising:
utilizing the on-chip oscillator to generate a predetermined frequency output;
receiving an external data input from an off-chip data source;
generating a comparison result by comparing the predetermined frequency output with the external data input; and
calibrating the predetermined frequency output by utilizing the comparison result.

2. The on-chip oscillating method of claim 1, wherein the step of generating the comparison result by comparing the predetermined frequency output with the external data input comprises:
detecting a phase difference between the predetermined frequency output and the external data input to generate a detection result; and
generating the comparison result pursuant to the detection result.

3. The on-chip oscillating method of claim 1, wherein the on-chip oscillator is an LC oscillator.

4. The on-chip oscillating method of claim 1, wherein the on-chip oscillator is a relaxation oscillator.

5. The on-chip oscillating method of claim 1, wherein the on-chip oscillator is a ring oscillator.

6. An on-chip oscillating apparatus which is able to calibrate its frequency, comprising:
an on-chip oscillator, arranged to generate a predetermined frequency output; and
a calibration unit, arranged to generate a comparison result by comparing the predetermined frequency output with an external data input received from an off-chip data source, and arranged to calibrate the predetermined frequency output according to the comparison result.

7. The on-chip oscillating apparatus of claim 6, wherein the calibration unit comprises:
a detection unit, arranged to detect a phase difference between the predetermined frequency output and the external data input to generate a detection result; and
a processing unit, arranged to generate the comparison result pursuant to the detection result.

8. The on-chip oscillating apparatus of claim 6, wherein the on-chip oscillator is an LC oscillator.

9. The on-chip oscillating apparatus of claim 6, wherein the on-chip oscillator is a relaxation oscillator.

10. The on-chip oscillating apparatus of claim 6, wherein the on-chip oscillator is a ring oscillator.
